(19) United States
(12) Patent Application Publication
(10) Pub. No.: US 2025/0113578 A1
(43) Pub. Date: Apr. 3, 2025

(54) METHOD FOR FORMING ELECTRODES, SEMICONDUCTOR DEVICE AND SEMICONDUCTOR WAFER

(71) Applicant: Infineon Technologies Austria AG, Villach (AT)

(72) Inventors: Winfried Kaindl, Unterhaching (DE); Christian Fachmann, Villach (AT)

(21) Appl. No.: 18/891,465

(22) Filed: Sep. 20, 2024

(30) Foreign Application Priority Data
Sep. 29, 2023 (DE) 102023126765.5

(51) Int. Cl. H01L 29/417; H01L 25/11; H01L 29/36; H01L 29/49; H01L 29/808

(52) U.S. Cl. CPC H10D 64/252; H01L 25/115; H10D 30/831; H10D 64/258; H10D 64/665; H10D 62/60

(57) ABSTRACT

Disclosed is a method for forming electrodes, a semiconductor device, and a semiconductor wafer. The semiconductor wafer includes: a plurality of semiconductor bodies and kerf regions arranged between the semiconductor bodies; at least one device electrode arranged above at least one of the semiconductor bodies; and at least one kerf electrode arranged above at least one of the kerf regions. The at least one device electrode includes a first device electrode layer patterned from a first electrically conducting layer and a second device electrode layer patterned from a second electrically conducting layer different from the first electrically conducting layer. The at least one kerf electrode includes a first kerf electrode layer patterned from the first electrically conducting layer and is devoid of a second kerf electrode layer.

### TECHNICAL FIELD

This disclosure relates in general to a method for forming electrically conducting electrodes, above a semiconductor body and a kerf region of a semiconductor wafer.

### BACKGROUND

Dependent on the specific type of semiconductor device implemented in a semiconductor body, various kinds of electrodes may be formed above the semiconductor body. The electrodes are connected to active device regions of the semiconductor device and may provide for an external connection to the active device regions. Electrodes formed above a semiconductor body of a vertical transistor device, for example, include a source electrode connected to source regions of the transistor device, a gate runner and a gate pad connected to gate electrodes of the transistor device, and a drain runner, for example.

Forming a semiconductor device may include a plurality of process sequences. Such process sequences may include implantation processes in which dopant atoms are implanted into the semiconductor body. The process sequences for forming semiconductor devices usually take place on a wafer level. That is, a plurality of semiconductor bodies included in a wafer are processed at the same time using the same process sequences. The wafer is separated at the end of the manufacturing processes in order to obtain a plurality of individual semiconductor bodies (dies, chips). The wafer includes the plurality of semiconductor bodies and kerf regions, which are regions located between the semiconductor bodies and which are at least partially removed when the wafer is separated.

In order to be able to monitor the quality of the manufacturing processes, test structures may be formed in the kerf regions using the same manufacturing processes used for forming the semiconductor devices. The quality of the manufacturing processes can be evaluated by measuring electric characteristics of the test structures, for example. In order to be able to measure electric characteristics of the test structures one or more electrodes connected to the test structures may be formed above the kerf region.

The same process sequences may be used for forming electrodes above the semiconductor bodies and electrodes above the kerf regions. Conventionally, electrodes of semiconductor devices, such as source electrodes, gate runners, or gate pads of transistor devices, include aluminum (Al) or copper (Cu). Having these materials in the kerf region when it comes to separating the wafer is undesirable because these materials tend to adhere to saw blades used for separating the wafer. This may negatively affect the sawing result. In a conventional process, electrodes formed above the kerf region are therefore removed after measuring the electrical characteristics of the test structures and before separating the wafer. This, however, is inconvenient.

There is therefore a need for an improved method for forming electrodes above semiconductor bodies and kerf regions of a wafer.

### SUMMARY

One example relates to a method. The method includes forming a device electrode above a semiconductor body of a semiconductor wafer, wherein the semiconductor wafer includes semiconductor bodies and kerf regions between the semiconductor bodies, and forming a kerf electrode above a kerf region. Forming the device electrode and the kerf electrode includes forming a first electrically conducting layer on top of an insulating layer formed above the semiconductor body and the kerf region, patterning the first electrically conducting layer to form a first device electrode layer and a first kerf electrode layer, forming a second electrically conducting layer on top of the insulating layer, the first device electrode layer, and the first kerf electrode layer, and patterning the second electrically conducting layer to form a second device electrode layer at least partially on top of the first device electrode layer and to remove the second electrically conducting layer from above the kerf region.

Another example relates to a semiconductor device. The semiconductor device includes a first device electrode and a second device electrode. The first device electrode includes a first device electrode layer and a second device electrode layer formed at least partially on top of the first device electrode layer, the second device electrode includes a first device electrode layer and a second device electrode layer formed at least partially on top of the first device electrode layer. A distance between the first device electrode layers of the first and second device electrodes is shorter than a distance between the second device electrode layers of the first and second device electrodes.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a top view of a semiconductor wafer including a plurality of semiconductor bodies and kerf regions between the semiconductor bodies;

FIGS. 2A-2F and 3A-3F illustrate one example of a method for forming an electrode above a semiconductor body and an electrode above the kerf region of a wafer;

FIGS. 4A-4D illustrate one example of a method for forming two electrodes spaced apart from each other above the semiconductor body;

FIG. 5 illustrates portions of the electrodes formed in the method according to FIG. 4A-4D in detail;

FIGS. 6A-6B each illustrate a top view of a transistor device according to one example;

FIG. 7 illustrates transistor cells according to one example that each include a gate electrode;

FIG. 8 illustrates one example of the gate electrodes in greater detail;

FIG. 9 illustrates one example of an edge region of a transistor device of the type illustrated in FIGS. 6A-6B;

FIGS. 10A-11C illustrate electrically conducting vias according to different examples that may be used in a transistor device of the type illustrated in FIG. 9;

FIG. 12 illustrates one example of the edge region illustrated in FIG. 9 in a section plane different from the section plane in FIG. 9;

FIG. 13 illustrates a vertical cross-sectional view of one portion of a transistor device including a drain runner;

FIG. 14 illustrates one example of a transistor device of the type illustrated in FIG. 13 in greater detail; and

FIG. 15 illustrates one example of a kerf region and adjoining regions of semiconductor bodies.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

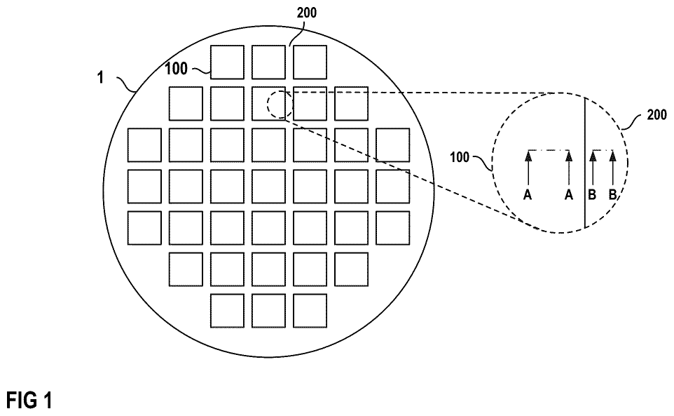

FIG. 1 schematically illustrates a top view of a semiconductor wafer 1. The semiconductor wafer 1 includes a plurality of semiconductor bodies 100 and kerf regions 200 arranged between the semiconductor bodies 100 and separating the semiconductor bodies 100 from one another. The wafer is a contiguous monocrystalline semiconductor wafer, for example, which is separated at the end of the manufacturing process to obtain a plurality of individual semiconductor bodies (dies) 100. The monocrystalline semiconductor material is a conventional monocrystalline semiconductor material such as, for example silicon (Si), silicon carbide (SiC), gallium arsenide (GaAs), gallium nitride (GaN), or the like.

During the manufacturing process, device regions of semiconductor devices are formed in the semiconductor bodies 100. The manufacturing process may include implantation processes, wherein in each implantation process dopant atoms are implanted into predefined regions of the semiconductor bodies 100. The manufacturing process may further include forming insulating layers and electrode layers above the wafer 1 before separating the wafer.

The number of semiconductor bodies 100 in the wafer 1 is dependent on the size of the individual semiconductor bodies 100 and the size of the wafer. The overall number is between several 10 and several 100, for example. The wafer 1 is separated by sawing along the kerf regions 200, for example. In this way, at least portions of the kerf regions 200 are removed.

During the process of manufacturing device regions of the semiconductor devices in the semiconductor bodies 100, test structures may be formed in the kerf regions 200. The test structures, which may also be referred to as PCM (Process Control Monitoring) structures are formed by at least some of the manufacturing processes that form the device regions of the semiconductor devices. Based on electrical characteristics of the test structures the quality of the manufacturing processes can be evaluated after the end of the manufacturing process. In the manufacturing process, a test structure may be formed for each of the semiconductor bodies 100. In this example, the number of test structures equals number of semiconductor bodies 100. According to another example, one test structure is formed for several semiconductor bodies. Providing test structures on a semiconductor wafer in order to be able to evaluate the manufacturing process is commonly known, so that no further explanation is required in this regard.

In order to be able to measure electrical characteristics of the test structures kerf electrodes are formed above the kerf regions 200 of the wafer 1. Furthermore, device electrodes are formed above the semiconductor bodies 100 of the wafer 1. The device electrodes are connected to device regions of semiconductor devices implemented in the semiconductor bodies 100, for example.

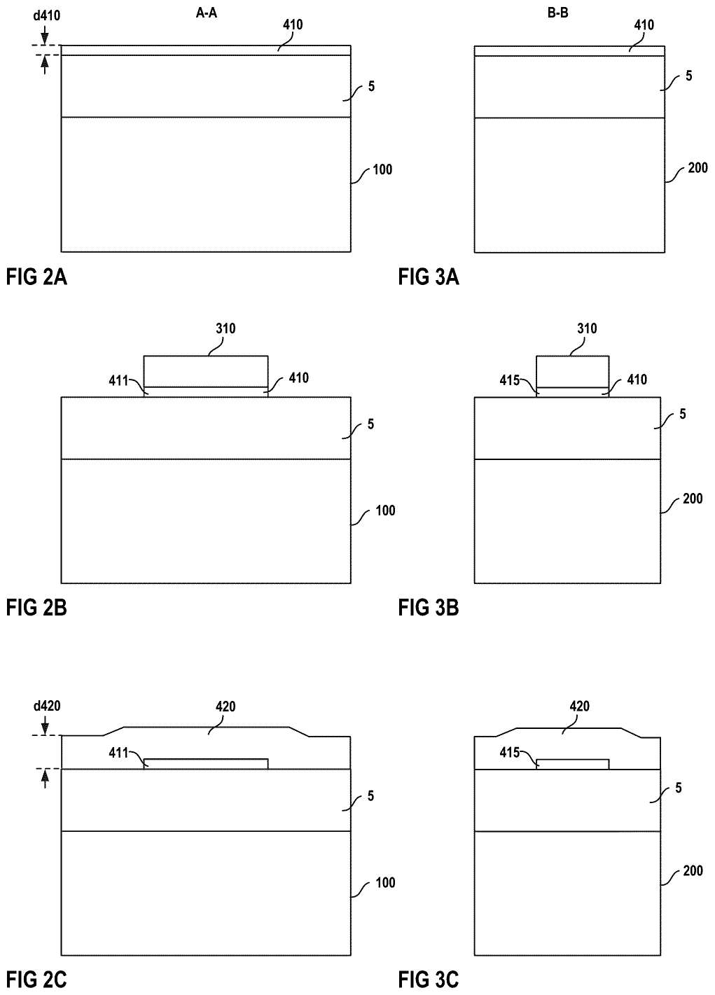

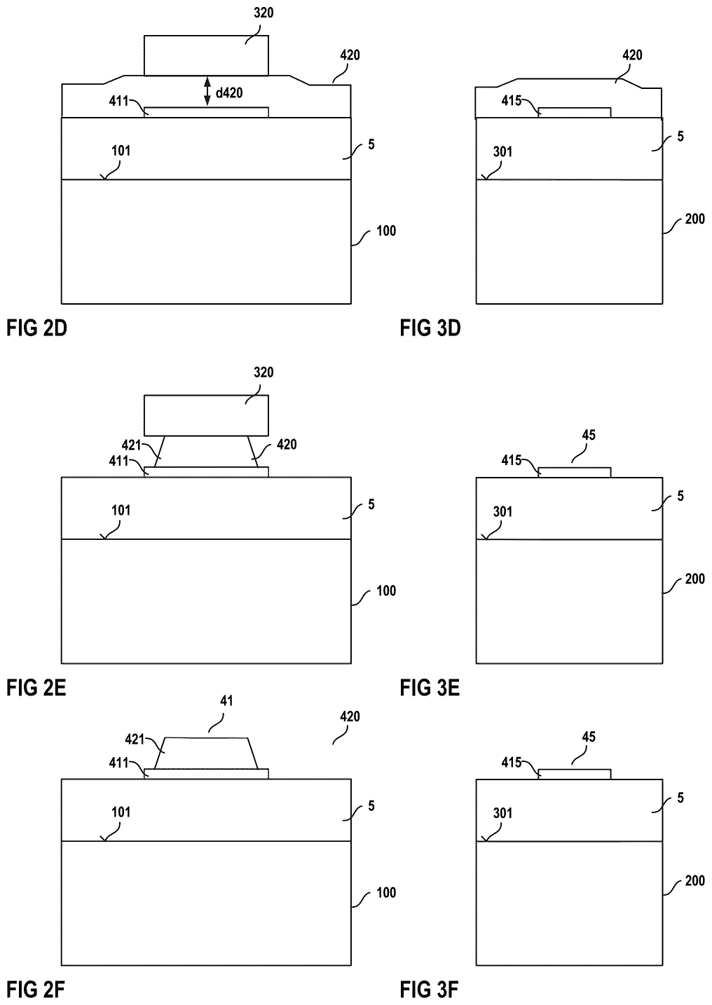

FIGS. 2A-2F and 3A-3F illustrate one example of a method for forming a device electrode 41 above a semiconductor body 100 and a kerf electrode 45 above a kerf region 200 of the semiconductor wafer 1. FIGS. 2A-2F each illustrate a vertical cross-sectional view of one portion of the semiconductor body 100 and FIG. 3A-3F each illustrate a vertical cross-sectional view of one portion of the kerf region 200 during the process of forming the electrodes 41, 45. The section plane illustrated in FIGS. 2A-2F may correspond to section plane A-A illustrated in FIG. 1, and the section plane illustrated in FIG. 3A-3F may correspond to section plane B-B illustrated in FIG. 1.

FIGS. 2A-2F and 3A-3F illustrate forming one device electrode and one kerf electrode. This, however, is only for illustration purposes. The same process may be used to form several device electrodes above the semiconductor body 100 and several kerf electrodes above the kerf region 200.

In FIGS. 2A-2F and 3A-3F only those features of the wafer are shown that relate to forming the device and kerf electrodes 41, 45. That is, device regions that may have been formed in the semiconductor body 100 before forming the device electrode 41 and one or more test structures that may have been formed in the kerf region 200 before forming the kerf electrode 45 are not illustrated.

Referring to FIGS. 2A and 3A, the method includes forming a first electrically conducting layer 410 on top of an insulating layer 5 formed above the semiconductor body 100 and the kerf region 200. Forming the insulating layer 5 above the semiconductor body and the kerf region 200 may include forming the insulating layer 5 above the entire wafer 1 before forming the device and kerf electrodes 41, 45.

The first electrically conducting layer 410 is formed on top of a surface 501 of the insulating layer 5. A thickness d410 of the first electrically conducting layer 410 is between 0.8 micrometers and 1.5 micrometers, for example. The thickness d410 of the first electrically conducting layer 410 is the dimension of the first electrically conducting layer in a direction perpendicular to the first surface 501 of the insulating layer.

According to one example, the first electrically conducting layer 410 comprises a metal such as tungsten (W) or titanium (Ti). According to one example, the first electrically conducting layer 410 is a homogeneous layer of the same material such as tungsten or titanium. According to another example, the first electrically conducting layer 410 includes two or more partial layers. According to one example, one of the partial layers is a tungsten layer and the thickness of each of the one or more other partial layers is less than 10% of the thickness of the tungsten layer.

According to one example, the first electrically conducting layer 410 includes a first partial layer including titanium (Ti), a second partial layer including titanium nitride (TiN), and a third partial layer including tungsten (W) The first partial layer may be formed on top of the insulating layer 5, the second partial layer may be formed on top of the first partial layer, and the third partial layer may be formed on top of the second partial layer. According to one example, a thickness of each of the first and second partial layers is less than 10% of the thickness of the third partial layer.

Referring to FIGS. 2B and 3B, the method further includes patterning the first electrically conducting layer 410 to form a first device electrode layer 411 above the semiconductor body 100 and a first kerf electrode layer 415 above the kerf region 200. Patterning the first electrically conducting layer 410 may include forming an etch mask 310 above the first electrically conducting layer 410 and etching the first electrically conducting layer 410 with the etch mask 310 in place. The etch mask 310 protects certain regions of the electrically conducting layer 410 from being etched and, therefore, essentially defines the size and the positions of the first device electrode layer 411 and the first kerf electrode layer 415. According to one example, the etching process for patterning the first electrically conducting layer 410 is an anisotropic etching process, such as a plasma etching process. FIGS. 2B and 3B show the semiconductor body 100 and the kerf region 200 after the etching process and with the etch mask 310 still in place.

Referring to FIGS. 2C and 3C, the method further includes removing the etch mask 310 and forming a second electrically conducting layer 420 above the insulating layer 5. That is, forming the second electrically conducting layer 420 includes forming the second electrically conducting layer on top of portions of the insulating layer 5 not covered by the first electrode layers 411, 415 and on top of the first electrode layers 411, 415.

The second electrically conducting layer 420 includes a metal such as aluminum (Al) or copper (Cu), or a metal alloy such as AlCu or AlSiCu, for example. AlSiCu is an alloy including aluminum, copper, and silicon. According to one example, the second electrically conducting layer 420 is a homogeneous layer including only one material. According to another example, the second electrically conducting layer includes two or more partial layers including different electrically conducting materials.

According to one example, the second electrically conducting layer 420 is thicker than the first electrically conducting layer 410. That is, a thickness d420 of the second electrically conducting layer 420 is greater than the thickness d410 of the first electrically conducting layer 410. According to one example, the thickness d420 of the second electrically conducting layer 420 is between 3 micrometers and 10 micrometers, in particular between 3 micrometers and 7 micrometers.

According to one example, the thickness d410 of the first electrically conducting layer 410 is less than 30% of the thickness d420 of the second electrically conducting layer 420.

The method for forming the device electrode 41 and the kerf electrode 45 further includes patterning the second electrically conducting layer 420 to form a second device electrode layer 412 at least partially on top of the first device electrode layer 411 and to remove the second electrically conducting layer 420 from above the kerf region 200. Patterning the second electrically conducting layer 420 may include forming an etch mask 320 above the second electrically conducting layer 420 and etching the second electrically conducting layer 420 with the etch mask 320 in place.

FIGS. 2D and 3D illustrate the second electrically conducting layer 420 after forming the etch mask 320. The etch mask 320 protects certain regions of the second electrically conducting layer 420 from being etched and, therefore, essentially defines the size and the position of the second device electrode layer 421. According to one example, the etching process for patterning the second electrically conducting layer 420 is an isotropic etching process, such as a wet etching process. In this type of process, portions of the second electrically conducting layer 420 below edge regions of the etch mask 320 are also etched, which needs to be considered in the design of the etch mask 320.

According to one example, the etching process for patterning the second electrically conducting layer 420 etches the second electrically conducting layer 420 selectively relative to the first electrode layers 411, 415, so that these first electrode layers 411, 415 remain in place. FIGS. 2E and 3E illustrate the semiconductor body 100 and the kerf region 200 after the etching process for patterning the second electrically conducting layer 420.

As can be seen from FIG. 3D and 3E, the etch mask 320 for a patterning the second electrically conducting layer 420 is such that the second electrically conducting layer 420 is removed from above the kerf region 200. Thus, in the kerf region 200 the kerf electrode 45 only includes the first kerf electrode layer 415. The device electrode 41 above the semiconductor body 100, however, includes the first device electrode layer 411 and the second device electrode layer 421 obtained by patterning the second electrically conducting layer 420. This is illustrated in FIGS. 2F and 3F that show the semiconductor body 100 and the kerf region 200 after removing the etch mask 320 for patterning the second electrically conducting layer 420.

In the method explained before, the thicker second electrically conducting layer 420 is removed from above the kerf regions 200 so that there is no risk of portions of the second electrically conducting layer 420 adhering to a saw blade when separating the wafer 1. The kerf electrode 45 is formed by portions of the first electrically conducting layer 410. The first electrically conducting layer 410 is thinner than the second electrically conducting layer 420 and may include a more of brittle material, such as tungsten or titanium, than the second electrically conducting layer 420, which may include aluminum or copper. Thus, portions of the first electrically conducting layer 410 forming the one or more kerf electrodes 45 do not negatively affect the separating process.

The test structure (not illustrated in the drawings) included in the kerf region is measured using the one or more kerf electrodes which are formed by the same process in which the one or more device electrodes 41 are formed above the semiconductor body 100. Thus, there is no additional process sequence that removes portions of the kerf electrodes after measuring the test structures and before separating the wafer.

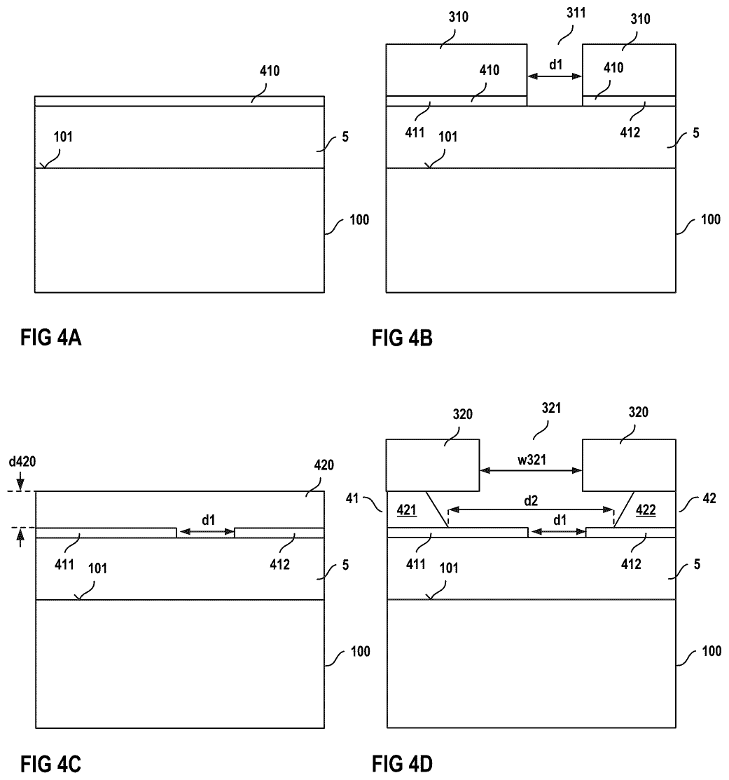

Another positive aspect of the method explained before is illustrated in FIGS. 4A-4D. Each of these figures shows a vertical cross-sectional view of one portion of the semiconductor body 100 above which two device electrodes 41, 42 spaced apart from each other are formed.

FIG. 4A shows a vertical cross-sectional view of the semiconductor body 100 and the insulating layer 5 after forming the first electrically conducting layer 410 above the insulating layer 5. FIG. 4B shows a vertical cross-sectional view of the semiconductor body 100, the insulating layer 5, and the first electrically conducting layer 410 after patterning the first electrically conducting layer 410 to form first device electrode layers 411, 412. Referring to FIG. 4B, patterning the first electrically conducting layer 410 includes etching the first electrically conducting layer 410 using an etch mask 310 that covers those portions of the first electrically conducting layer 410 that form the first device electrode layers 411, 412.

The etch mask 310 includes an opening 311. Referring to the above, the etching process is an anisotropic etching process, for example. In this example, the dimension of the opening 311 essentially defines a distance between the first device electrode layers 411, 412.

FIG. 4C illustrates the arrangement illustrated in FIG. 4B after removing the etch mask 310 and forming the second electrically conducting layer 420.

FIG. 4D illustrates the arrangement shown in FIG. 4C after patterning the second electrically conducting layer 422 to form second device electrode layers 421, 422 such that each of the second device electrode layers 421, 422 is at least partially formed on top of a respective first device electrode layer 411, 412. Each first device electrode layer 411, 412 and the corresponding second device electrode layer 421, 422 forms one of the device electrodes 41, 42. That is, in the example illustrated in FIG. 4D, first device electrode layer 411 and second device electrode layer 421 form a first device electrode 41, and first device electrode layer 412 and second device electrode layer 422 form a second device electrode 42.

As explained above, patterning the second electrically conducting layer 420 may include an isotropic etching process. In this process, portions of the second electrically conducting layer 420 below edge regions of the etch mask 320 adjacent to an opening 321 of the etch mask 320 are also etched. Thus, a distance d2 between neighboring second device electrode layers 421, 422 may be larger than a corresponding dimension w321 of the opening 321 in the etch mask 320.

According to one example, a minimum distance between two neighboring second device electrode layers 421, 422 that can be achieved in an etching process of the type illustrated in FIG. 4D is dependent on the thickness d420 of the second electrically conducting layer and is between 2 times and 3 times the thickness d420. That is, in the example illustrated in FIG. 4D, the distance d2 between the two second device electrode layers 421, 422 is at least between 1.5 times and 3 times the thickness d420.

Given a minimum thickness of the second electrically conducting layer 420 of about 3 micrometers, the minimum distance that can be achieved between the second device electrode layers 421, 422 is 6 micrometers. The distance dl between the first device electrode layers 411, 412 is much lower, for example.

According to one example, the distance between dl between the first device electrode layers 411, 412 is between 0.5 micrometers and 5 micrometers, in particular between 1 micrometer and 3 micrometers.

In the example illustrated in FIG. 4D, the first device electrode layers 411, 412 may act as a barrier layer that serves to prevent or at least reduce a diffusion of impurity atoms into the insulating layer 5 and the semiconductor body 100. According to one example, impurity atoms are atoms from a mold compound that may be formed on top of the semiconductor device after the wafer 1 has been separated into the individual devices. Such impurity atoms may negatively affect the functionality of the semiconductor devices.

It is therefore desirable to reduce a size of gaps between the first device electrode layers 411, 412 acting as barrier layers as much as possible. This can be achieved by the method explained before, in which the first and second electrically conducting layers 410, 420 are patterned by separated processes. Patterning the first electrically conducting layer using an anisotropic etching process, for example, makes it possible to produce smaller gaps between the first device electrode layers 411, 412 than between the second device electrode layers 421, 422 that are formed by patterning the second electrically conducting layer 420 using an isotropic etching process, for example.

FIG. 5 illustrates the arrangement illustrated in FIG. 4D after removing the second etch mask 320 and illustrates the finished first and second device electrodes 41, 42. Referring to the above, a minimum distance between neighboring second device electrode layers, such as second device electrode layers 421, 422 illustrated in FIG. 5, is larger than a minimum distance between neighboring first device electrode layers, such as first device electrode layers 411, 412 illustrated in FIG. 5. According to one example, in those regions in which the first and second device electrodes 41, 42 are adjacent to one another, the second device electrode layers 421, 422 are formed such that edges of the second device electrode layers 421, 422 are spaced apart from corresponding edges of the first device electrode layers 411, 412. That is, in the example illustrated in FIG. 5, the first device electrode layer 411 of the first device electrode 41 protrudes below the second device electrode layer 421 of the first device electrode 41 in the direction of the second device electrode 42. In FIG. 5, p1 denotes the dimension by which the first device electrode layer 411 protrudes below the second device electrode layer 421. Furthermore, in the example illustrated in FIG. 5, the first device electrode layer 412 of the second device electrode 42 protrudes below the second device electrode layer 422 of the second device electrode 42. In FIG. 5, p2 denotes the dimension by which the first device electrode layer 412 protrudes below the second device electrode layer 422.

The distance between the second device electrode layers 421, 422 is essentially given by the first protrusion p1 plus the distance between the first device electrode layers 411, 412 plus the second protrusion, d2=p1+d1+p2.

According to one example, the first and second device electrodes 41, 42 are asymmetric such that the first and second protrusions p1, p2 are different. According to one example, the first protrusion p1 is at least 1.2 times, 1.5 times, 2 times, 2.5 times, 3 times, 4 times, or 5 times the second protrusion p2.

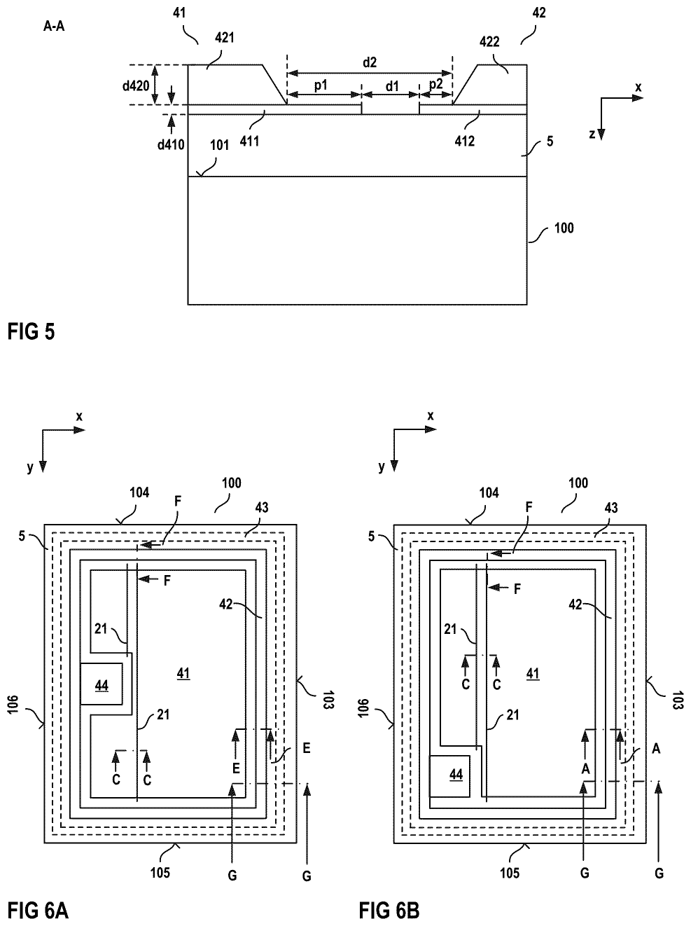

Depending on the specific type of semiconductor device the first and second device electrodes 41, 42 may have different functions. According to one example the first device electrode 41 is a source electrode and the second device electrode 42 is a gate runner of a transistor device. Top views of two different transistor devices that each include the first device electrode 41 as a source electrode and the second device electrode 42 as a gate runner are illustrated in FIGS. 6A and 6B. Each of FIGS. 6A and 6B illustrates a top view of the overall transistor device after separating a wafer 1 into the individual devices. After separating the wafer 1 to form the individual transistor devices, the transistor device may at least be partially encapsulated by a mold compound, wherein portions of the mold compound may adjoin the device electrodes and portions of the insulating layer 5 not covered by the device electrodes. Such mold compound, however, is not illustrated in FIGS. 6A and 6B.

Referring to FIGS. 6A and 6B, the gate runner 42 may surround the source electrode 41 in lateral directions of the semiconductor body 100. Lateral directions are directions that are essentially parallel to a first surface 101 of the semiconductor body 100. Referring to FIG. 5, the first surface 101 of the semiconductor body 100 is the surface on top of which the insulating layer 5 is formed.

As explained herein further below, transistor cells 10 of the transistor device may be formed in an inner region of the semiconductor body 100 below the source electrode 41. The source electrode 41, in particular the first device electrode layer 411 acts as a barrier layer above the transistor cells 10. By implementing the source electrode 41 and the gate runner 42 in an asymmetric way explained above, the distance between the inner region, where transistor cells are integrated, and the gap between the first device electrode layers 411, 412 can be maximized in order to reduce the risk of impurity atoms reaching the transistor cells.

Referring to FIGS. 6A and 6B, the transistor device may further include a gate pad 44 that is connected to the gate runner 44. The gate pad 44 forms a gate node G or is connected to a gate node G of the transistor device. The gate pad 44 may adjoin the gate runner 42, as illustrated in FIGS. 6A and 6B. Alternatively, the gate pad 44 is spaced apart from the gate runner 42 and a resistor (gate resistor) is connected between the gate pad 44 and the gate runner 42.

The gate pad 44 is a device electrode that may be formed by the same process as the source electrode 41 and the gate runner 42. In the example in which the gate pad 44 adjoins the gate runner 42, the gate pad 44 and the gate runner 42 are formed as one contiguous device electrode.

In the example illustrated in FIG. 6A, the gate pad 44 is arranged at a position that is essentially in the middle between two opposing sidewalls 103, 106 of the semiconductor body 100. In the example according to FIG. 6B, the gate pad 44 is arranged at a position that is close to a corner formed by two adjacent sidewalls 105, 106 of the semiconductor body 100. The sidewalls 103-106 of the semiconductor body 100 result from separating the wafer 1 into the individual semiconductor bodies 100.

The semiconductor body 100 may include an inner region and an edge region. The inner region is essentially the region of the semiconductor body 100 that is arranged below the source electrode 41. The edge region surrounds the inner region and is arranged between the inner region and the sidewalls 103-106. In the inner region of the semiconductor body 100 a plurality of transistor cells are integrated. Each of the transistor cells includes a gate electrode 21. The transistor cells are out of view in FIGS. 6A and 6B. Examples of the transistor cells are explained herein further below.

Just for the purpose of illustration, the position of two gate electrodes 21 relative to the source electrode 41, the gate runner 42, and the gate pad 44 is illustrated by bold lines in FIGS. 6A and 6B. In the example illustrated in FIGS. 6A and 6B, the gate electrodes 21 are elongated electrodes which are spaced apart from each other in a first lateral direction x. Longitudinal directions of the gate electrodes 21 correspond to a second lateral direction y perpendicular to the first lateral direction x, for example.

The gate electrode 21 of each transistor cell is electrically connected to the gate runner 42 at at least one longitudinal end of the respective gate electrode 21. Connections between the gate electrodes 21 and the gate runner 42 are not illustrated in FIG. 6. Connections between the gate electrodes 21 and the gate runner 42 are explained herein further below.

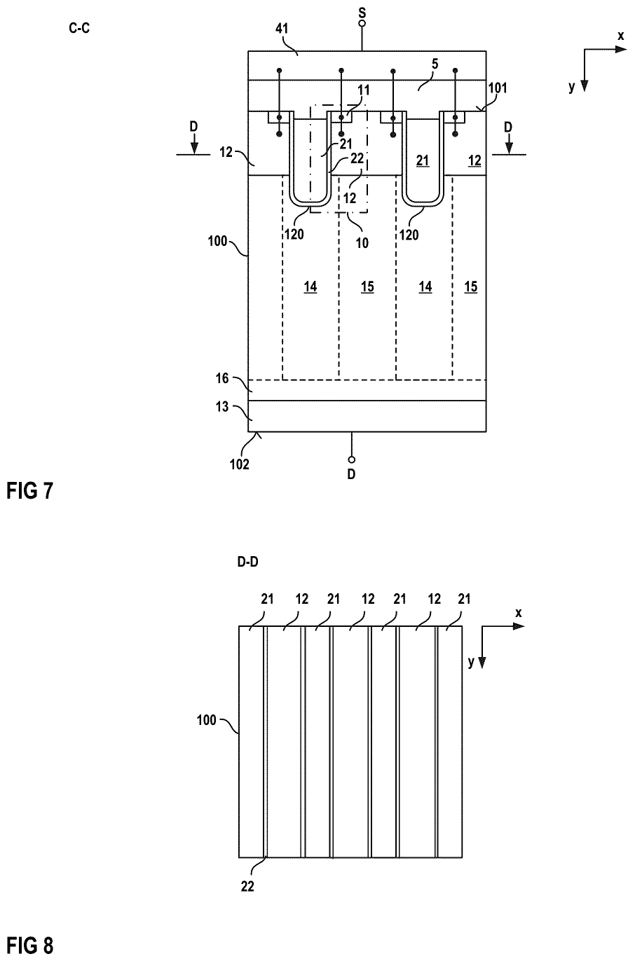

One example of the transistor cells 10 that may be integrated in the semiconductor body 100 below the source electrode 41 is illustrated in FIG. 7. FIG. 7 shows a vertical cross-sectional view of one portion of the semiconductor body 100 in which the transistor cells 10 are integrated. The vertical cross-sectional view of the transistor cells illustrated in FIG. 7 is a cross-sectional view in section planes C-C illustrated in FIGS. 6A and 6B, for example.

Referring to FIG. 7, each transistor cell 10 includes a source region 11 of a first doping type, a body region 12 of a second doping type complementary to the first doping type, and a gate electrode 21. The gate electrode 21 is adjacent to the body region 12, is dielectrically insulated from the body region 12 by a gate dielectric 22, and is arranged in a gate trench 120 extending from the first surface 101 of the semiconductor body 100 into the semiconductor body 100.

Referring to FIG. 7, source and body regions 11, 12 of two neighboring transistor cells 10 may be arranged in a mesa region between neighboring gate trenches 120. In this example, the body regions 12 of the two neighboring transistor cells 10 may be formed by one contiguous doped region of the second doping type. Furthermore, two (other) neighboring transistor cells may share the gate electrode 21. That is, the gate electrodes 21 of two neighboring transistor cells may be formed by one contiguous electrode arranged in one gate trench 120.

The gate electrodes 21 include an electrically conducting material. Examples of the electrically conducting material include doped polysilicon, or a metal such as tungsten (W), titanium (Ti), copper (Cu), aluminum (Al), or the like. The gate dielectric 22 includes an oxide, for example. According to one example, the oxide is silicon oxide (SiO₂).

The source electrode 41 either forms the source node S or is connected to the source node S of the transistor device. The source electrode 41 is only schematically illustrated in FIG. 7, so that the first and second device electrode layers 411, 412 are not shown.

The source electrode 41 is electrically connected to the source and body regions 11, 12 of the transistor cells 10. Connections between the source electrode 41 and the source and body regions 11, 12 are only schematically illustrated in FIG. 7. Such connections may be implemented using electrically conducting vias that extend from the source electrode 41 through the insulating layer 5 down to the source and body regions 11, 12. Examples of such vias are explained herein further below.

The insulating layer 5 is formed on top of the first surface 101 and on top of the gate electrodes 21 and separates the source electrode 41 from the semiconductor body 100 and the gate electrodes 21.

Referring to FIG. 7, the transistor device further includes a drift region 14 of the first doping type. The drift region 14 adjoins the body regions 12 of the transistor cells 10 so that PN junctions are formed between the body regions 12 and the drift region 14. Furthermore, in the vertical direction, the drift region 14 is arranged between the body regions 12 and a drain region 13 of the first doping type. The drain region 13 may adjoin a second surface 102 opposite the first surface 101.

Optionally, a buffer region 16 of the first doping type and having a doping concentration that is higher than the doping concentration of the drift region 14 and lower than the doping concentration of the drain region 13 is arranged between the drift region 14 and the drain region 13.

Referring to FIG. 7 and as explained above, the gate trenches with the gate electrodes 21 may be spaced apart from each other in the first lateral direction x. According to one example, the gate electrodes 21 are implemented as stripe electrodes (elongated electrodes). In this example, longitudinal directions of the gate electrodes 21 correspond to a second lateral direction perpendicular to the first lateral direction x.

One example of elongated gate electrodes 21 is illustrated in FIG. 8. FIG. 8 illustrates one portion of the semiconductor body 100 in a first horizontal section plane D-D shown in FIG. 7 that cuts through the gate trenches 120 with the gate electrodes 21 and the gate dielectrics 22. The horizontal sectional plane D-D is essentially parallel to the first surface 101. In the example illustrated in FIG. 8, the gate electrodes 21 longitudinally extend in the second lateral direction y.

According to one example, the transistor device is implemented as a superjunction transistor device. In this example, the transistor device includes a plurality of compensation regions 15 (illustrated in dashed lines) that are spaced apart from each other in a lateral direction of the semiconductor body 100. Each of the compensation regions 15 is adjacent to a respective portion of the drift region 14.

Just for the purpose of illustration, in the example illustrated in FIG. 7, the compensation regions 15 are spaced apart from each other in the first lateral direction x. According to another example (not illustrated) the compensation regions 15 are spaced apart from each other in the second lateral direction y.

The transistor device can be operated in an on-state or an off-state. In the on-state, there are conducting channels in the body regions 12 along the gate dielectrics 22 between the source regions 11 and the drift region 14. For this, the drift region 14 adjoins the gate dielectric 22 and the body region 12 of at least one of the transistor cells 10.

Furthermore, each of the optional compensation regions 15 is adjacent to at least one of the portions of the drift region 14 and is connected to the source electrode 41. In the example illustrated in FIG. 7, each of the compensation regions 15 adjoins the body region 12 of at least one transistor cell and is connected to the source electrode 41 via the respective body region 12.

The transistor device can be operated in a conventional way by applying a drive voltage (gate-source voltage) between the gate electrodes 21 and the source electrode 41. The transistor device is in the on-state (conducting state) when the drive voltage is such that conducting channels are generated in the body regions 12 along the gate dielectrics 22 between the source regions 11 and the drift region 14. The transistor device is in the off-state (blocking state) when the electrically conducting channels are interrupted.

The transistor device can be implemented as an N-type transistor device or as a P-type transistor device. An N-type transistor device, for example, is in the on- state, when the drive voltage is higher than a predefined positive threshold voltage and in the off-state, when the drive voltage is below the threshold voltage.

In an N-type transistor device, the doped regions of the first doping type are N-type regions and the doped regions of the second doping type are P-type regions. In a P-type transistor device, the doped regions of the first doping type are P-type regions and the doped regions of the second doping type are N-type regions.

The source regions 11, the body regions 12, the drift and compensation regions 14, 15, the buffer region 16, and the drain region 13 may also be referred to as (active) device regions of the transistor device.

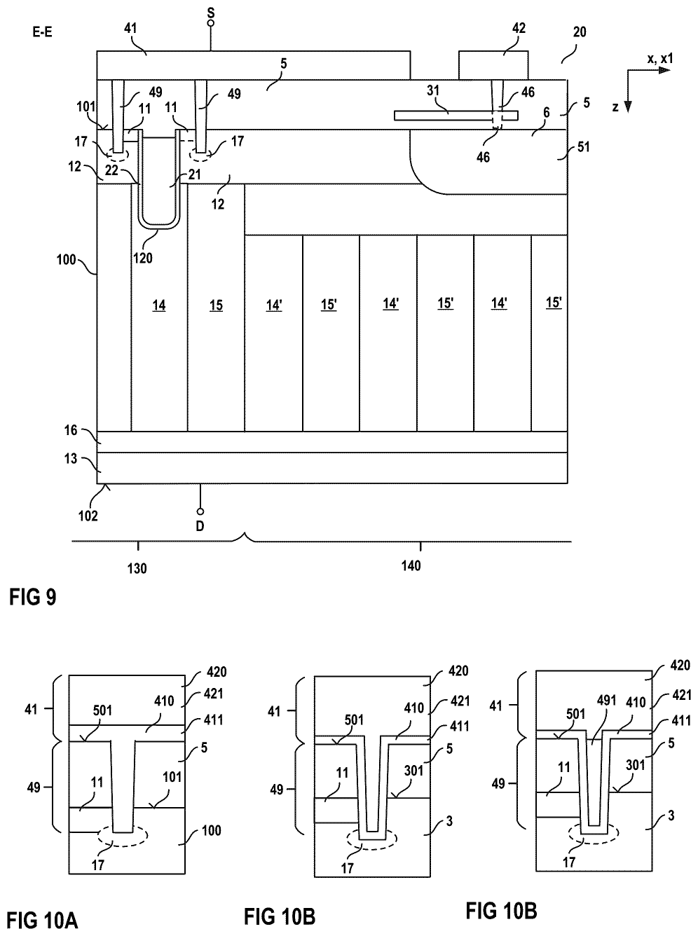

FIG. 9 illustrates a vertical cross sectional view of a transistor device with transistors cells of the type illustrated in FIG. 7 in a vertical section plane E-E (see, FIGS. 6A and 6B) that cuts through a portion of the inner region 130 and a portion of an edge region 140 of the semiconductor body 100. The inner region 130 is the region in which the transistor cells are integrated and on top of which the source electrode 41 is arranged. The edge region 140 surrounds the inner region 130 in lateral directions and is the region on top of which the gate runner 42 and the gate pad 44 are arranged.

The plurality of transistor cells include an edge transistor cell, which is the transistor cell that is closest to the edge region 140. The edge transistor cell may include a source region 11 (illustrated in dashed lines in FIG. 8). Alternatively, the source region 11 is omitted in the edge transistor cell.

The transistor device illustrated in FIG. 9 is a superjunction transistor device, which, in addition to the drift region 14, includes compensation regions 15. According to one example, illustrated in FIG. 9, drift and compensation regions are not only arranged in the inner region 130 but are also arranged in the edge region 140. Drift regions arranged in the edge region 140 may be referred to as edge drift regions 14′, and compensation regions arranged in the edge region 140 may be referred to as edge compensation regions 15′.

Referring to the above, the source and body regions 11, 12 of the transistor cells are connected to the source electrode 41. According to one example illustrated in FIG. 9, the source and body regions 11, 12 are connected to the source electrode 41 through electrically conducting vias 49 that extend from the source electrode 41 through the insulating layer 5 to the source and body regions 11, 12 in the semiconductor body 100. Optionally, each transistor cell 10 includes a body contact regions 17 of the second doping type that provides for an ohmic contact between the body region 12 and the respective electrically conducting via 49. The body contact regions 17 have a higher doping concentration than the body regions 12.

In the edge region, the transistor device may include an edge termination structure. According to one example, the edge termination structure includes an edge trench 6 extending from the first surface 101 into the edge region 140 of the semiconductor body 100 and filled with an electrically insulating layer 51. The edge trench 6 with the insulating layer 51 may surround the inner region 130 in lateral directions.

Furthermore, the edge termination structure may include a field electrode 31 arranged above the edge trench 6 and electrically connected to the gate runner 42 through an electrically conducting via 46. The field electrode 31 includes doped polysilicon, for example.

The gate runner 42 is only schematically illustrated in FIG. 9. That is, the first and second device electrode layers 412, 422 forming the gate runner 42 are not illustrated in FIG. 9.

According to one example, the electrically conducting vias 49 connecting the source and body regions 11, 12 of the transistor cells 10 to the source electrode 41 are formed by the same process that forms the source electrode 41. This is explained with reference to FIGS. 10A-10C, which each illustrate a detailed view of one of the electrically conducting vias 49 extending from the source electrode 41 through the insulating layer 5 into the semiconductor body 100.

Forming via 49 includes forming a trench that extends from the surface 501 of the insulating layer 5 through the insulating layer 5 into the semiconductor body 100 before forming the first electrically conducting layer 410. FIGS. 10A and 10B show the electrically conducting via 49 after forming the first and second electrically conducting layers 410, 420. As can be seen, the first electrically conducting layer 410, more specifically, the first device electrode layer 411, at least partially forms the via 49. That is, the first device electrode layer 411 at least partially fills the via trench. In the example illustrated in FIG. 10A, the first device electrode layer 411 completely fills the via trench. In this example, the via 49 is formed by a portion of the first device electrode layer 411 in the via trench.

In the example illustrated in FIG. 10B, the first device electrode layer 411 lines a bottom and sidewalls of the via trench but does not completely fill the via trench. A residual trench remaining after forming the first device electrode layer 411 is filled by the second electrically conducting layer 420, more specifically, by the second device electrode layer 421. In this example, the via 49 is formed by portions of the first electrically conducting layer 410 and portions of the second electrically conducting layer 420.

According to another example illustrated in FIG. 10C, the first device electrode layer 411 lines the bottom and the sidewalls of the via trench and a void 491 remains in the via trench after forming the second device electrode layer 421.

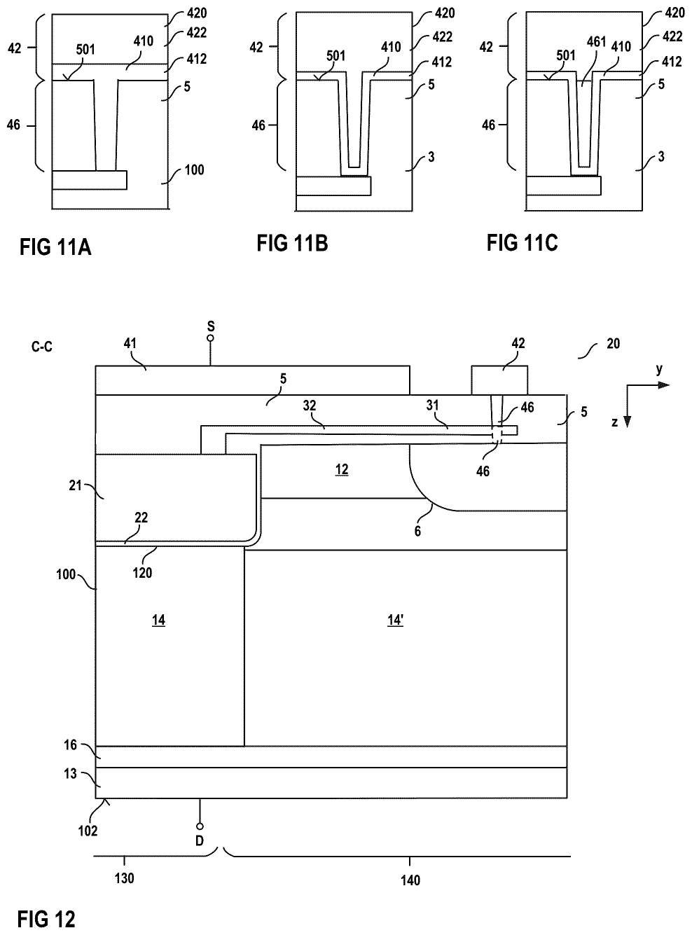

Equivalently to forming via 49 by the same process that forms the source electrode 41, the via 46 connecting the gate runner 42 to the field electrode 31 can be formed by the same process that forms the gate runner 42. Examples of the electrically conducting via 46 are illustrated in FIGS. 11A-11C. In the example illustrated in FIG. 11A, the first device electrode layer 412 of the gate runner 42 completely fills the via trench extending in the insulating layer 5 to the field electrode 31. In the example illustrated in FIG. 11B, the first device electrode layer 412 of the gate runner 42 lines a bottom and sidewalls of the via trench, wherein a residual trench remaining after forming the first electrically conducting layer 410 is filled by the second electrically conducting layer 420, more specifically, by the second device electrode layer 422 of the gate runner 42.

According to another example illustrated in FIG. 11C, the first device electrode layer 412 lines the bottom and the sidewalls of the via trench and a void 461 remains in the via trench after forming the second device electrode layer 422.

Referring to the above, each of the gate electrodes 21 is connected to the gate runner 42 at at least one longitudinal end. One example for connecting the gate electrodes 21 to the gate runner 42 is illustrated in FIG. 12.

FIG. 12 shows a vertical cross-sectional view of the transistor device in a section plane F-F (see, FIGS. 6A and 6B) that is essentially parallel to the longitudinal directions of the gate electrodes 21 and that cuts through one of the gate electrodes 21. FIG. 12 shows a portion of the inner region 130 and the edge region 140 of the semiconductor body 100.

In the example illustrated in FIG. 12, the gate electrode 21 is connected to the gate runner 42 via the field electrode 31. For this, a contact finger 32 extends, in the insulating layer 5, from the field electrode 31 to the gate electrode 21 and is connected to the gate electrodes 21 at a longitudinal end of the gate electrode 21.

The field electrode 31 and the contact finger can be formed by the same process, so that the field electrode 31 and the contact finger 32 can be formed by one contiguous electrode layer. The electrode layer is an electrically conducting layer such as a doped polysilicon layer, for example.

According to one example, illustrated in dashed lines in FIGS. 6A and 6B, the transistor device further includes a drain runner 43. The drain runner 43 is arranged between the gate runner 42 and the sidewalls 103-106 and surrounds the gate runner 42 and the source electrode 41 in lateral directions.

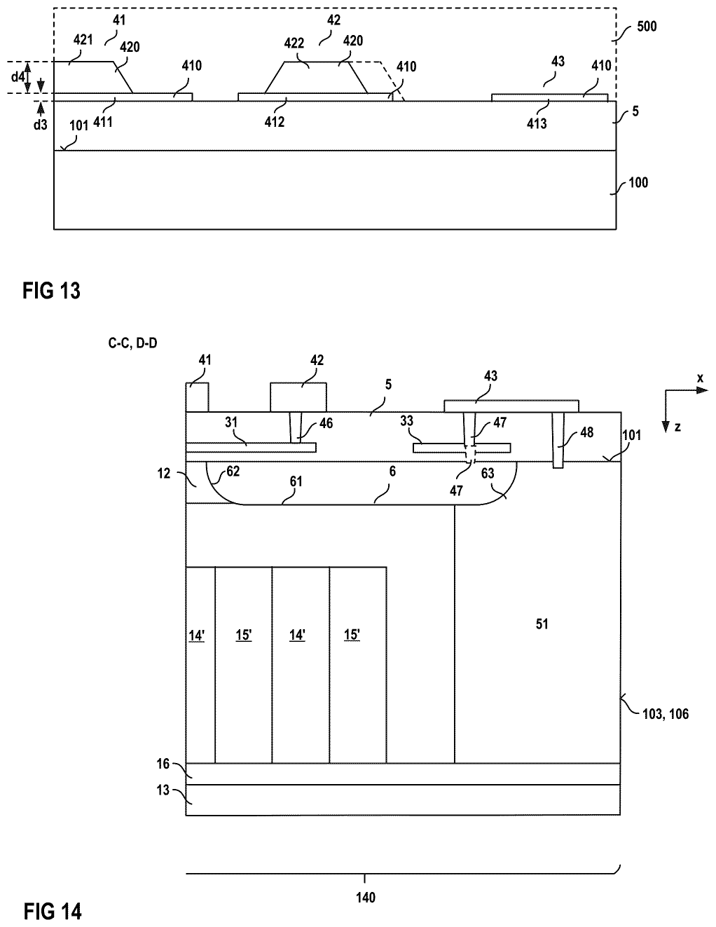

FIG. 13 illustrates a vertical cross-sectional view of a portion of the insulating layer 5 on top of which the source electrode 41, the gate runner 42 and the drain runner 43 are arranged. The section plane illustrated in FIG. 13 corresponds to section plane G-G shown in FIGS. 6A and 6B, for example. In FIG. 13, the semiconductor body 100 is only schematically illustrated; active device regions are not shown.

The drain runner 43 is formed by the same process that forms the device electrodes, such as the source electrode 41 and the gate runner 42, and the kerf electrode 45. The drain runner 43 is formed in the same way as the kerf electrode 45. That is, the drain runner 43 includes a first device electrode layer 413 that is obtained by patterning the first electrically conducting layer 410. The drain runner 43 includes the first device electrode layer 413 only. That is, the drain runner 43 does not include a second device electrode layer obtained by patterning the second electrically conducting layer 420.

Referring to the above, a mold compound 500 (illustrated in dashed lines in FIG. 13) may be formed above the device electrodes 41, 42, 43 after separating the wafer 1. The second device electrode sections 421, 422 that are based on the relatively thick second electrically conducting layer 420 may include relatively sharp edges. Thermal stress of the mold compound 50 may result in damages of the mold compound along these sharp edges. At least in the region of the drain runner 43 this risk can be reduced by manufacturing the drain runner 43 only based on the (relatively thin) first electrically conducting layer 410. Different from the source electrode 41 and the gate runner 42 the drain runner 43 does not require a low resistance.

FIG. 14 illustrates a vertical cross-sectional view of one example of a transistor device that includes a drain runner 43 of the type illustrated in FIG. 13. The source electrode 41 and the gate runner 42 are only schematically illustrated in FIG. 14. The example illustrated in FIG. 14 is based on the example illustrated in FIG. 9, for example.

Referring to FIG. 14, the transistor device includes a field stop region 51 of the first doping type that extends from the drain regions 13 or the buffer region 16 along the sidewalls 103-106 to the first surface 101. The drain runner 43 is electrically connected to the field stop region 51. According to one example, the drain runner 43 is connected to the field stop region 51 through an electrically conducting via 48. The electrically conducting via 48 may be produced in the same way as the vias 49, 46 explained before.

Furthermore, the drain runner 46 is connected to second field electrode 33 embedded in the insulating layer. The drain runner 43 is connected to second field electrode 33 through an electrically conducting via 47 extending from the drain runner 46 through portions of the insulating layer 5 to the second field electrode 33.

With regard to the via 46 connecting the gate runner 42 to the first field electrode 31 and the via 47 connecting the drain runner 43 to the second field electrode 33 it should be noted that these vias are in contact with the respective field electrode. This may include that there via 46, 47 contact the respective field electrode 31, 33 at a surface. According to another example, illustrated in dashed lines in FIGS. 12 and 14, the via 46, 47 extends into the respective field electrode 31, 33 or even through the respective field electrode 31, 33.

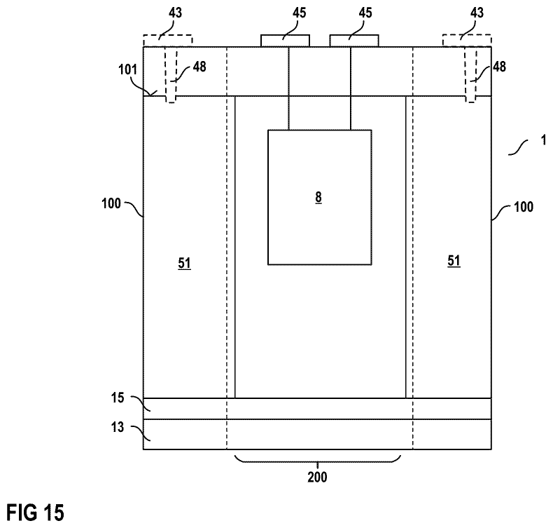

FIG. 15 schematically illustrates a vertical cross-sectional view of one portion of the kerf region 200 located between two semiconductor bodies 100. According to one example, transistor devices are implemented in the semiconductor bodies 100. Optional drain runners 43 of the transistor devices are illustrated in dashed lines in FIG. 15.

Just as an example, FIG. 15 illustrates two kerf electrodes 45 of the wafer 1. Each of these kerf electrodes 45 is connected to a test structure 8 arranged in the kerf region 200 of the wafer. Connections between the kerf electrode 45 and the test structure 8 as well as the test structure 8 are only schematically illustrated in FIG. 15.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
forming a device electrode above a semiconductor body of a semiconductor wafer, wherein the semiconductor wafer comprises semiconductor bodies and kerf regions between the semiconductor bodies; and
forming a kerf electrode above a kerf region,
wherein forming the device electrode and the kerf electrode comprises:
forming a first electrically conducting layer on top of an insulating layer formed above the semiconductor body and the kerf region;
patterning the first electrically conducting layer to form a first device electrode layer and a first kerf electrode layer;
forming a second electrically conducting layer on top of the insulating layer, the first device electrode layer, and the first kerf electrode layer; and
patterning the second electrically conducting layer to form a second device electrode layer at least partially on top of the first device electrode layer and to remove the second electrically conducting layer from above the kerf region.

2. The method of claim 1, wherein the first electrically conducting layer comprises at least one of tungsten and titanium.

3. The method of claim 1, wherein the second electrically conducting layer comprises at least one of aluminum and copper.

4. The method of claim 1, wherein a thickness of the first electrically conducting layer is less than 30% of a thickness of the second electrically conducting layer.

5. The method of claim 1, wherein a thickness of the first electrically conducting layer is between 0.8 micrometers and 1.5 micrometers.

6. The method of claim 1, wherein a thickness of the second electrically conducting layer is between 3 micrometers and 10 micrometers.

7. The method of claim 1,
wherein the device electrode is a first device electrode,
wherein the method further comprises forming a second device electrode spaced apart from the first device electrode,
wherein forming the second device electrode comprises:
forming a first device electrode layer of the second device electrode by patterning the first electrically conducting layer; and
forming a second device electrode layer of the second device electrode at least partially on top of the first device electrode layer of the second device electrode by patterning the second electrically conducting layer.

8. The method of claim 7, further comprising:
forming the first device electrode layers of the first and second device electrodes to be spaced apart from each other less than the second device electrode layers of the first and second device electrodes.

9. The method of claim 8, further comprising:
forming the first device electrode layers of the first and second device electrodes to have a mutual distance of between 0.5 micrometers and 2 micrometers.

10. The method of claim 8, further comprising:
forming the second device electrode layers of the first and second device electrodes to have a mutual distance of more than 5 micrometers.

11. The method of claim 7, wherein the first device electrode layer of the first device electrode protrudes from the second device electrode layer of the first device electrode in a direction of the second device electrode, and wherein the first device electrode layer of the second device electrode protrudes from the second device electrode layer of the second device electrode in a direction of the first device electrode.

12. The method of claim 1, further comprising:
forming a third device electrode that only includes a first device electrode layer obtained by patterning the first electrically conducting layer.

13. A semiconductor device, comprising:
a first device electrode; and
a second device electrode,
wherein the first device electrode comprises a first device electrode layer and a second device electrode layer formed at least partially on top of the first device electrode layer,
wherein the second device electrode comprises a first device electrode layer and a second device electrode layer formed at least partially on top of the first device electrode layer,
wherein a distance between the first device electrode layers of the first and second device electrodes is shorter than a distance between the second device electrode layers of the first and second device electrodes.

14. The semiconductor device of claim 13, wherein the first device electrode layer of the first device electrode protrudes below the second device electrode layer of the first device electrode in a direction of the second device electrode by a first protrusion, wherein the first device electrode layer of the second device electrode protrudes below the second device electrode layer of the second device electrode in a direction of the first device electrode by a second protrusion, and wherein the first protrusion is greater than the second protrusion.

15. The semiconductor device of claim 14, wherein a dimension of the first protrusion is at least 1.2 times a dimension of the second protrusion.

16. The semiconductor device of claim 13, wherein the semiconductor device is a transistor device, wherein the first device electrode is a source electrode, and wherein the second device electrode is a gate runner.

17. The semiconductor device of claim 16, wherein the transistor device comprises a plurality of transistor cells, wherein each of the transistor cells includes a source region and a body region connected to the source electrode, and wherein each of the transistor cells includes a gate electrode connected to the gate runner.

18. A semiconductor wafer, comprising:
a plurality of semiconductor bodies and kerf regions arranged between the semiconductor bodies;
at least one device electrode arranged above at least one of the semiconductor bodies; and
at least one kerf electrode arranged above at least one of the kerf regions,
wherein the at least one device electrode comprises a first device electrode layer patterned from a first electrically conducting layer and a second device electrode layer patterned from a second electrically conducting layer different from the first electrically conducting layer,
wherein the at least one kerf electrode comprises a first kerf electrode layer patterned from the first electrically conducting layer and is devoid of a second kerf electrode layer.
